(19) United States
(12) Patent Application Publication
(10) Pub. No.: US 2020/0193120 A1
(43) Pub. Date: Jun. 18, 2020

(54) FINGERPRINT IDENTIFICATION APPARATUS

(71) Applicant: Novatek Microelectronics Corp., Hsinchu (TW)

(72) Inventor: I-Hsiu Chen, Taipei City (TW)

(73) Assignee: Novatek Microelectronics Corp., Hsinchu (TW)

(21) Appl. No.: 16/218,447

(22) Filed: Dec. 12, 2018

(51) Int. Cl. G06K 9/00; H01L 27/32

(52) U.S. Cl. CPC G06K 9/0004; H01L 27/3227; H01L 27/323

(57) ABSTRACT

A fingerprint identification apparatus for detecting a fingerprint image of a finger is provided. The fingerprint identification apparatus includes a display, an optical sensor, and a control device. The display is configured to emit light and has a fingerprint imaging area. The control device drives a region of the display at the periphery of the fingerprint imaging area to emit light to the finger when the finger touches the fingerprint imaging area, and the optical sensor is configured to receive light reflected from the finger touching the fingerprint imaging area to determine the fingerprint image of the finger.

### BACKGROUND

### Technical Field

The disclosure relates to a fingerprint identification apparatus for detecting a fingerprint image of a finger capable of providing a good quality of fingerprint image and having low manufacturing cost.

### Description of Related Art

Currently, in the market, an optical fingerprint sensor is placed under the display so as to be paired with the display. The display serves as a light source and emits light to the finger. After that, the light is reflected to the optical fingerprint sensor in order to obtain a fingerprint image. When the ambient light is strong, the part having long wavelength of the ambient light easily penetrates the finger and reaches the optical fingerprint sensor. As a result, the fingerprint image is blurred.

The current solution is that a multilayer filter is added in front of the optical fingerprint sensor to block the light having long wavelength and allow the light having short wavelength to pass through. Since the part having short wavelength of the ambient light is filtered out by the finger itself, the effect of the ambient light can be eliminated. However, on the one hand, adding the multilayer filter causes the cost to increase, on the other hand, the penetration rate of the light having short wavelength is reduced.

Another way is using in-display fingerprint sensor, it means that the optical fingerprint sensor is formed in the display. This technique also faces a problem about strong ambient light. If the multilayer filter is adopted, the coating process must be combined into the process to make the display, and there is a dilemma about passing range when using the multilayer filter. On the one hand, the red, green, and blue lights need to pass through the multilayer filter in order to display image. On the other hand, the red light easily reaches the finger and then enters the optical fingerprint sensor, so, under the strong ambient light condition, the fingerprint collecting process is affected. Another approach is that the multilayer filter is only formed on the optical fingerprint sensor, and the red light passes through the other parts. However, the disadvantage is that the patterning process of the multilayer filter is more complicated.

### SUMMARY

The disclosure is directed to a fingerprint identification apparatus for detecting a fingerprint image of a finger capable of providing a good quality of fingerprint image and having low manufacturing cost.

A fingerprint identification apparatus for detecting a fingerprint image of a finger of the disclosure includes a display, an optical sensor, and a control device. The display is configured to emit light and has a fingerprint imaging area. The control device drives a region of the display at the periphery of the fingerprint imaging area to emit light to the finger when the finger touches the fingerprint imaging area, and the optical sensor is configured to receive light reflected from the finger touching the fingerprint imaging area to determine the fingerprint image of the finger.

In one embodiment of the disclosure, the display includes a plurality of pixels, and each of the pixels includes a red subpixel. When the finger touches the fingerprint imaging area, the control device drives the red subpixels at the region of the display at the periphery of the fingerprint imaging area to emit red light to the finger.

In one embodiment of the disclosure, the control device is a thin film transistor circuitry disposed in the display.

In one embodiment of the disclosure, the optical sensor comprises a plurality of photosensors.

In one embodiment of the disclosure, the optical sensor is disposed in the display.

In one embodiment of the disclosure, the optical sensor is disposed under the display.

In one embodiment of the disclosure, the fingerprint identification apparatus further includes a collimator disposed between the display and the optical sensor.

In one embodiment of the disclosure, the fingerprint identification apparatus further includes a lens disposed between the display and the optical sensor.

A fingerprint identification apparatus for detecting a fingerprint image of a finger of the disclosure includes a display, an optical sensor, a filter layer, a plurality of first color filters, and a control device. The display has a fingerprint imaging area and is configured to have a plurality of pixels. The optical sensor includes a plurality of first photosensors and is disposed in the display. The filter layer is disposed in the display and is disposed above the pixels and the optical sensor, and the filter layer is configured to block infrared light and allow visible light to pass through. The first color filters are disposed between the filter layer and the first photosensors. The first color filters are configured to block red light, and each of the first color filters covers one of the first photosensors. The control device drives the pixels at the fingerprint imaging area to emit visible light to the finger when the finger touches the fingerprint imaging area, and each of the first photosensors receives light passing through the filter layer and the corresponding first color filter from the finger to determine a first fingerprint image of the finger.

In one embodiment of the disclosure, the control device is a thin film transistor circuitry disposed in the display.

In one embodiment of the disclosure, each of the pixels includes a red subpixel, a blue subpixel, and a green subpixel.

In one embodiment of the disclosure, the light passing through the filter layer and the corresponding first color filter from the finger to each of the first photosensors is green light and blue light.

In one embodiment of the disclosure, the filter layer is an infrared light cut filter layer, and each of the first color filters is a cyan color filter.

In one embodiment of the disclosure, the fingerprint image of the finger is determined according to the first finger image.

In one embodiment of the disclosure, the fingerprint identification apparatus further includes a plurality of second color filters, the optical sensor further includes a plurality of second photosensors. The filter layer is disposed above the second photosensors. The second color filters are disposed between the filter layer and the second photosensors, each of the second color filters covers one of the second photosensors, and each of the second photosensors receives light passing through the filter layer and the corresponding second color filter from the finger to determine a second fingerprint image of the finger.

In one embodiment of the disclosure, the light passing through the filter layer and the corresponding second color filter from the finger to each of the second optical sensors is red light.

In one embodiment of the disclosure, wherein the filter layer is an infrared light cut filter layer, each of the first color filters is a cyan color filter, and each of the second color filters is a red color filter.

In one embodiment of the disclosure, the fingerprint image of the finger is determined according to the first fingerprint image and the second fingerprint image.

In one embodiment of the disclosure, the first photosensors and the second photosensors are arranged in chess board manner.

Based on the above, in one embodiment of the disclosure, the optical sensor receives both the red light and the infrared light, which are transmitted from the finger and carry image information about the fingerprint of the finger, in order to determine the fingerprint image of the finger. Since the red light is transmitted from the region at the periphery of the fingerprint imaging area of the display, the transmitting path of the red light from the finger to the optical sensor is the same or parallel to the transmitting path of the infrared light of the ambient light. As a result, the quality of the fingerprint image of the finger is not decreased. In addition, since the infrared light of the ambient light is also be used to determine the fingerprint image, the fingerprint identification apparatus is not affected by the external environment. Further, when the red light is emitted, the fingerprint imaging area of the display does not emit light. Therefore, the contrast in the fingerprint image is not reduced by the light which is emitted from the fingerprint imaging area of the display.

In another embodiment of the disclosure, only the green light and the blue light, which are necessary to form the fingerprint image of the finger, can enter the photosensors of the optical sensor. The red light and the infrared light of the ambient light are prevented from entering the photosensors of the optical sensor. Therefore, the fingerprint identification apparatus is not affected by the external environment (or the ambient light/sunlight), so as to enhance the quality of the fingerprint image. Further, the existing manufacturing process of the display includes the process to manufacture the color filter. Therefore, manufacturing the color filter is easy, and the cost of the total manufacturing process is low.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic view of a fingerprint identification apparatus according to the first embodiment of the disclosure.

FIG. 1B is a schematic view illustrating a finger and a fingerprint imaging area of a display of the fingerprint identification apparatus according to the first embodiment of the disclosure.

FIG. 2A is a schematic view of a fingerprint identification apparatus according to the second embodiment of the disclosure.

FIG. 2B is a schematic view of a fingerprint identification apparatus according to the third embodiment of the disclosure.

FIG. 3 is a schematic view of a fingerprint identification apparatus according to the fourth embodiment of the disclosure.

FIG. 4A is a schematic view of a fingerprint identification apparatus according to the fifth embodiment of the disclosure.

FIG. 4B is a schematic view of arrangement of photosensors in the fifth embodiment of the disclosure.

FIG. 5A is a view showing the first fingerprint image in the fifth embodiment of the disclosure.

FIG. 5B is a view showing the second fingerprint image in the fifth embodiment of the disclosure.

### DESCRIPTION OF THE EMBODIMENTS

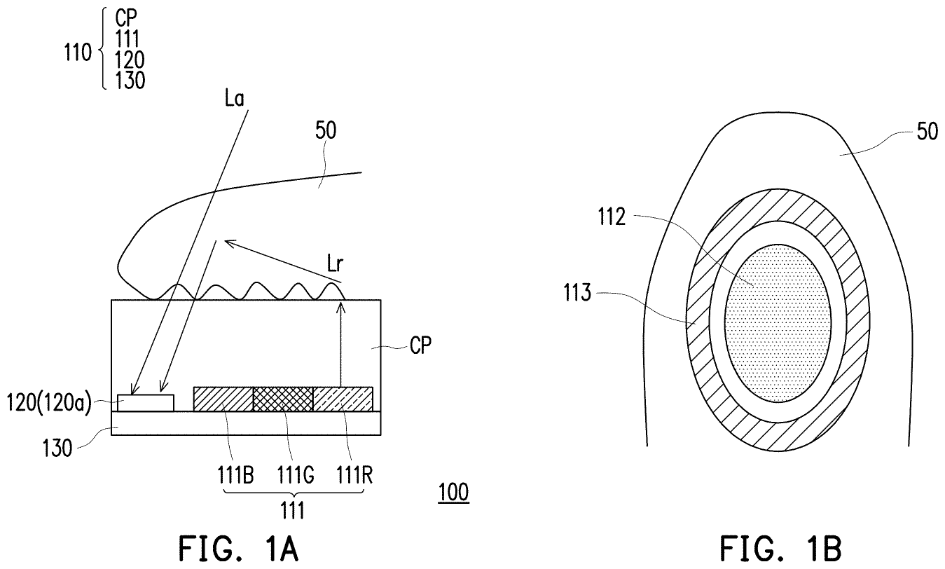

FIG. 1A is a schematic view of a fingerprint identification apparatus according to the first embodiment of the disclosure. FIG. 1B is a schematic view illustrating a finger and a fingerprint imaging area of a display of the fingerprint identification apparatus according to the first embodiment of the disclosure. As shown in FIG. 1A, a fingerprint identification apparatus 100 for detecting a fingerprint image of a finger 50 of the present embodiment includes a display 110, an optical sensor 120, and a control device 130. The display 110 has a cover and panel CP. In addition, the display 110 is configured to emit light and has a fingerprint imaging area 112 as shown in FIG. 1B. In the present embodiment, the display 110 may be an organic light-emitting diode display (OLED) which provides touch function, the disclosure is not limited thereto. The optical sensor 120 includes a plurality of photosensors 120a. Only one photosensor 120a is shown in FIG. 1A as an example, the disclosure is not limited thereto. In addition, the optical sensor 120 and the control device 130 are disposed in the display 110. The control device 130 drives a region 113 of the display 110 at the periphery of the fingerprint imaging area 112 of the display 110 to emit light to the finger 50 when the finger 50 touches the fingerprint imaging area 112 as shown in FIG. 1A. The optical sensor 120 is configured to receive light reflected from the finger 50 touching the fingerprint imaging area 112 to determine the fingerprint image of the finger 50.

To be more specific, the display 110 includes a plurality of pixels 111, and each of the pixels 111 includes a red subpixel 111R, a green subpixel 111G, and a blue subpixel 111B. Only one pixel 111 is shown in FIG. 1A as an example, the disclosure is not limited thereto. The control device 130 is a thin film transistor (TFT) circuitry disposed in the display 110. When the finger 50 touches the fingerprint imaging area 112, the control device 130 drives the red subpixels 111R at the region 113 of the display 110 at the periphery of the fingerprint imaging area 112 to emit a red light Lr to the finger 50. The green subpixels 111G, and the blue subpixels 111B at the region 113 of the display 110 at the periphery of the fingerprint imaging area 112 are not driven to emit light.

It should be noted here, the illuminance of sunlight or ambient light is the greatest and is about 200 times greater than the illuminance of light emitted from the display of a general mobile phone. To be more specific, the illuminance of light emitted from the display of a general mobile phone is about 500 (lux), the illuminance of sunlight or ambient light at noon is about 100000 (lux). Additionally, within the spectrum of the ambient light, the infrared light cannot be seen by human eye but can be sensed by a silicon sensor, such as the optical sensor 120 of the present embodiment.

The finger in general, such as the finger 50 of the present embodiment, can block the ambient light. For example, the finger can block most of the blue light and the green light in the ambient light, the ratio of the blue light and the green light in the ambient light passing through the finger is about 1 over 10000, and the ratio of the red light in the ambient light passing through the finger is about 1 over 1000. However, the ratio of the infrared light in the ambient light passing through the finger is a few over 1000.

Therefore, after the red light Lr is emitted to the finger 50, the red light Lr may pass through the interface between and display 110 and the finger 50, then scatters inside the finger 50, and finally be reflected to reach the photosensors 120a of the optical sensor 120. In addition, the infrared light La of the ambient light passes through the finger 50 and also reach the photosensors 120a of the optical sensor 120. Hence, the optical sensor 120 receives both the red light Lr and the infrared light La, which are transmitted from the finger 50 and carry image information about the fingerprint of the finger 50, in order to determine the fingerprint image of the finger 50.

Specifically, since the red light Lr is transmitted from the region 113 at the periphery of the fingerprint imaging area 112 of the display 110, the transmitting path of the red light Lr from the finger 50 to the optical sensor 120 is the same or parallel to the transmitting path of the infrared light La of the ambient light. As a result, the quality of the fingerprint image of the finger 50 is not decreased. In other words, a good quality of the fingerprint image of the finger 50 is obtained without any additional element, such as band pass filter, and without sacrificing the display quality of the display 110. Further, since the infrared light La of the ambient light, which can pass through the finger 50 and can be sensed by the optical sensor 120, is also be used to determine the fingerprint image, the fingerprint identification apparatus 100 is not affected by the external environment (or the ambient light/sunlight), and the quality of the fingerprint image is not decreased.

On the other hand, when the red light Lr is emitted, the fingerprint imaging area 112 of the display 110 does not emit light. Therefore, the contrast in the fingerprint image of the finger 50 is not reduced by the light which is emitted from the fingerprint imaging area 112 of the display 110 and then reflected at the interface between the display 110 and the finger 50 to the optical sensor 120. Further, when the ambient light is strong, it may not necessary to emit the red light Lr to determine the fingerprint image of the finger 50.

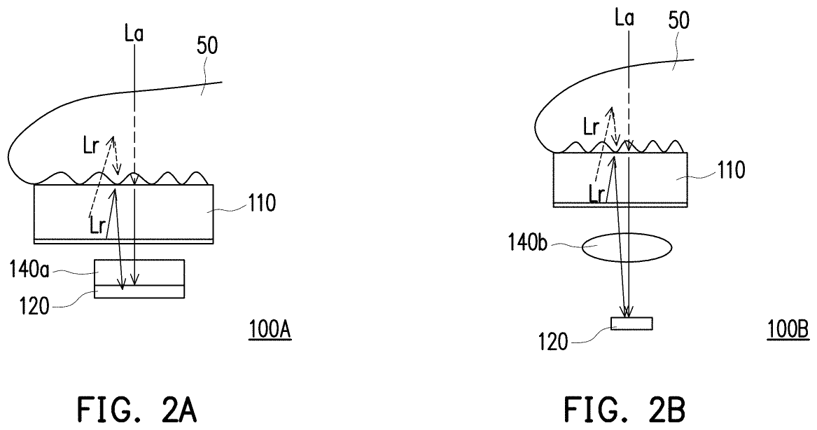

Compared to the first embodiment, the same reference number is used for the same or similar elements/components in the following embodiments. FIG. 2A is a schematic view of a fingerprint identification apparatus according to the second embodiment of the disclosure. A fingerprint identification apparatus 100A in the present embodiment is similar to the fingerprint identification apparatus 100 in the first embodiment, only the differences are described hereinafter. In the fingerprint identification apparatus 100A of the present embodiment, the optical sensor 120 is disposed under the display 110. The fingerprint identification apparatus 100A further includes a collimator 140a disposed between the display 110 and the optical sensor 120. The collimator 140a is used to align the red light Lr and the infrared light La of the ambient light before reaching the optical sensor 120. In other words, the transmitting path of the red light Lr is parallel to the transmitting path of the infrared light La of the ambient light after the red light Lr and the infrared light La pass through the collimator 140a.

FIG. 2B is a schematic view of a fingerprint identification apparatus according to the third embodiment of the disclosure. A fingerprint identification apparatus 100B in the present embodiment is similar to the fingerprint identification apparatus 100A in the second embodiment, only the differences are described hereinafter. In the present embodiment, the fingerprint identification apparatus 100B further includes a lens 140b, instead of a collimator, disposed between the display 110 and the optical sensor 120. The lens 140b is used to focus the red light Lr and the infrared light La of the ambient light on the optical sensor 120.

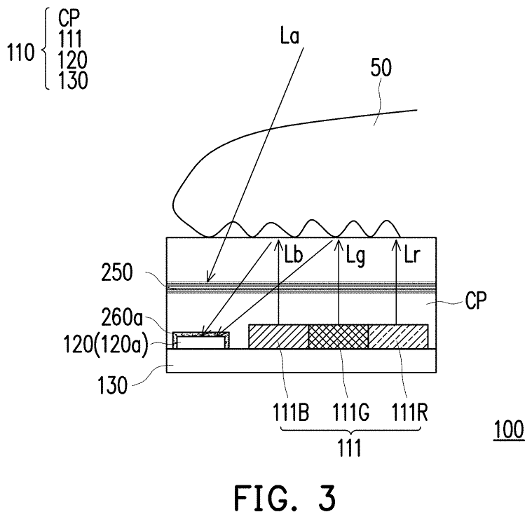

FIG. 3 is a schematic view of a fingerprint identification apparatus according to the fourth embodiment of the disclosure. A fingerprint identification apparatus 200 for detecting the fingerprint image of the finger 50 of the present embodiment includes the display 110, the optical sensor 120, a filter layer 250, a plurality of color filters 260a, and the control device 130. The display 110 has the fingerprint imaging area 112 as shown in FIG. 1B and the display 110 is configured to have a plurality of pixels 111. The optical sensor 120 includes a plurality of photosensors 120a and the optical sensor 120 is disposed in the display 110. Only one of the photosensors 120a and one of the pixels 111 are shown in FIG. 3 as an example, the disclosure is not limited thereto. The filter layer 250 is disposed in the display 110 and the filter layer 250 is disposed above the pixels 111 and the optical sensor 120. The filter layer 250 is configured to block infrared light and allow visible light to pass through. The color filters 260a are disposed between the filter layer 250 and the photosensors 120a. The color filters 260a are configured to block red light, and each of the color filters 260a covers one of the photosensors 120a. The control device 130 drives the pixels 111 at the fingerprint imaging area 112 to emit visible light to the finger 50 when the finger 50 touches the fingerprint imaging area 112, and each of the photosensors 120a receives light passing through the filter layer 250 and the corresponding color filter 260a from the finger 50 to determine the fingerprint image of the finger 50.

To be more specific, the control device 130 is a thin film transistor (TFT) circuitry disposed in the display 110. Each of the pixels 111 includes a red subpixel 111R, a blue subpixel 111B, and a green subpixel 111G. The filter layer 250 is an infrared light cut filter layer, and each of the color filters 260a is a cyan color filter. However, the disclosure is not limited thereto. Therefore, when the finger 50 touches the fingerprint imaging area 112 of the display 110, the control device 130 drives the red subpixels 111R, the blue subpixels 111B, and the green subpixels 111G of the pixels 111 at the fingerprint imaging area 112 to emit a red light Lr, a blue light Lb, and a green light Lg to the finger 50. After being emitted from the blue subpixels 111B and the green subpixels 111G, the blue light Lb and the green light Lg are reflected at the interface between the display 110 and the finger 50 and then are transmitted to the photosensors 120a of the optical sensor 120. On the one hand, the infrared light La of the ambient light passing through the finger 50 is blocked by the filter layer 250, which is an infrared light cut filter layer, and cannot reach the photosensors 120a of the optical sensor 120. On the other hand, the red light Lr may scatter inside the finger 50 and then is transmitted toward the photosensors 120a of the optical sensor 120. However, the color filters 260a, which are cyan color filters, covering the photosensors 120a block the red light Lr and prevent the red light Lr from entering the photosensors 120a. Hence, the light passing through the filter layer 250 and the corresponding color filter 260a from the finger 50 to each of the photosensors 120a is the green light Lg and blue light Lb. In other words, the light entering the photosensors 120a is the green light Lg and the blue light Lb. As a result, the optical sensor 120 receives both the green light Lg and blue light Lb, which are transmitted from the finger 50 and carry image information about the fingerprint of the finger 50, in order to determine the fingerprint image of the finger 50.

In the present embodiment, only the green light Lg and blue light Lb, which are necessary to form the fingerprint image of the finger 50, can enter the photosensors 120a of the optical sensor 120. The red light Lr and the infrared light La of the ambient light are prevented from entering the photosensors 120a of the optical sensor 120. Therefore, the fingerprint identification apparatus 200 is not affected by the external environment (or the ambient light/sunlight), so as to enhance the quality of the fingerprint image.

Further, the existing manufacturing process of the display includes the process to manufacture the color filter. Therefore, manufacturing the color filter is easy, and the cost of the total manufacturing process is low.

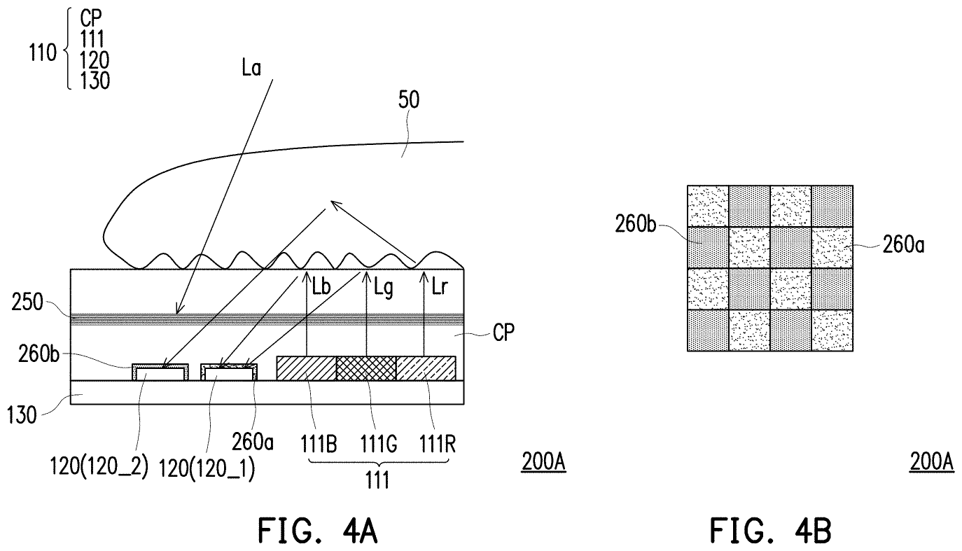

FIG. 4A is a schematic view of a fingerprint identification apparatus according to the fifth embodiment of the disclosure. FIG. 4B is a schematic view of arrangement of photosensors in the fifth embodiment of the disclosure. A fingerprint identification apparatus 200A of the present embodiment is similar to the fingerprint identification apparatus 100 of the fourth embodiment, only the differences are described hereinafter. In the present embodiment, the fingerprint identification apparatus 200A includes a plurality of first color filters 260a and a plurality of second color filters 260b. The optical sensor 120 further includes a plurality of first photosensors 120_1 and a plurality of second photosensors 120_2. The filter layer 250 is disposed above the first photosensors 120_1 and the second photosensors 120_2. The first color filters 260a are disposed between the filter layer 250 and the first photosensors 120_1, and the second color filters 260b are disposed between the filter layer 250 and the second photosensors 120_2. Each of the first color filters 260a covers one of the first photosensors 120_1, and each of the second color filters 260b covers one of the second photosensors 120_2. Each of the first photosensors 120_1 receives light passing through the filter layer 250 and the corresponding first color filter 260a from the finger 50 to determine the first fingerprint image of the finger 50. In addition, and each of the second photosensors 120_2 receives light passing through the filter layer 250 and the corresponding second color filter 260b from the finger 50 to determine the second fingerprint image of the finger 50. The light passing through the filter layer 250 and the first color filter 260a from the finger 50 to each of the photosensors 120_1 is the green light and blue light. In addition, the light passing through the filter layer 250 and the second color filter 260b from the finger 50 to each of the photosensors 120_2 is the red light.

To be more specific, the filter layer 250 is an infrared light cut filter layer, each of the first color filters 260a is a cyan color filter, and each of the second color filters 260b is a red color filter. When the finger 50 touches the fingerprint imaging area 112 of the display 110, the control device 130 drives the red subpixels 111R, the blue subpixels 111B, and the green subpixels 111G of the pixels 111 at the fingerprint imaging area 112 to emit a red light Lr, a blue light Lb, and a green light Lg to the finger 50. After being emitted from the blue subpixels 111B and the green subpixels 111G, the blue light Lb and the green light Lg are reflected at the interface between the display 110 and the finger 50 and then are transmitted to the photosensors 120_1 of the optical sensor 120. However, the second color filters 260b, which are red color filters, prevent the blue light Lb and the green light Lg from entering the photosensors 120_2 of the optical sensor 120. In addition, after being emitted from the red subpixels 111R, the red light Lr may pass through the interface between and display 110 and the finger 50, then scatters inside the finger 50, and finally be reflected to reach the photosensors 120_2 of the optical sensor 120. However, the first color filters 260a, which are cyan color filters, prevent the red light Lr from entering the photosensors 120_1 of the optical sensor 120. In addition, the infrared light La of the ambient light passing through the finger 50 is blocked by the filter layer 250, which is an infrared light cut filter layer, and cannot reach the photosensors 120_1 and 120_2 of the optical sensor 120. As a result, the light passing through the filter layer 250 and the corresponding first color filter 260a from the finger 50 to each of the first photosensors 120_1 is the green light Lg and the blue light Lb. The light passing through the filter layer 250 and the corresponding second color filter 260b from the finger 50 to each of the second optical sensors 120_2 is the red light Lr.

In the present embodiment, the first photosensors 120_1 and the second photosensors 120_2 are arranged in chess board manner, so the first color filters 260a and the second color filters 260b are also arranged in chess board manner as shown in FIG. 4B. Further, on the one hand, the first photosensors 120_1 receive the green light Lg and the blue light Lb passing through the filter layer 250 and the first color filters 260a from the finger 50 to determine the first fingerprint image of the finger 50. On the other hand, the second photosensors 120_2 receive the red light Lr passing through the filter layer 250 and the second color filters 260b from the finger 50 to determine the second fingerprint image of the finger 50. Consequently, the fingerprint image of the finger 50 is determined according to the first fingerprint image and the second fingerprint image, so as to improve the accuracy of the fingerprint identification apparatus 200A. Further, the fingerprint identification apparatus 200A is not affected by the external environment (or the ambient light/sunlight).

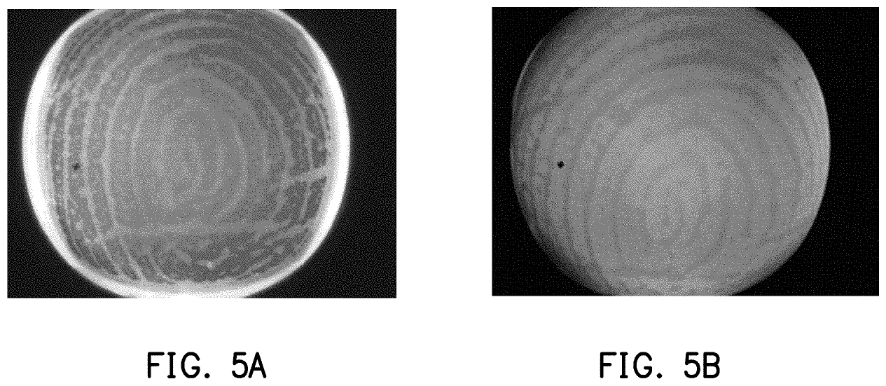

FIG. 5A is a view showing the first fingerprint image in the fifth embodiment of the disclosure. FIG. 5B is a view showing the second fingerprint image in the fifth embodiment of the disclosure. As shown in FIG. 5A and FIG. 5B, the first fingerprint image and the second fingerprint image have opposite tone or contrast tone. To be more specific, the ridges of the fingerprint are depicted by darker color in the first fingerprint image, but the ridges of the fingerprint are depicted by brighter color in the second fingerprint image. In addition, the valleys of the fingerprint are depicted by brighter color in the first fingerprint image, but the valleys of the fingerprint are depicted by darker color in the second fingerprint image.

Summarily, in one embodiment of the disclosure, the optical sensor receives both the red light and the infrared light, which are transmitted from the finger and carry image information about the fingerprint of the finger, in order to determine the fingerprint image of the finger. Since the red light is transmitted from the region at the periphery of the fingerprint imaging area of the display, the transmitting path of the red light from the finger to the optical sensor is the same or parallel to the transmitting path of the infrared light of the ambient light. As a result, the quality of the fingerprint image of the finger is not decreased. In addition, since the infrared light of the ambient light is also be used to determine the fingerprint image, the fingerprint identification apparatus is not affected by the external environment. Further, when the red light is emitted, the fingerprint imaging area of the display does not emit light. Therefore, the contrast in the fingerprint image is not reduced by the light which is emitted from the fingerprint imaging area of the display.

In another embodiment of the disclosure, only the green light and the blue light, which are necessary to form the fingerprint image of the finger, can enter the photosensors of the optical sensor. The red light and the infrared light of the ambient light are prevented from entering the photosensors of the optical sensor. Therefore, the fingerprint identification apparatus is not affected by the external environment (or the ambient light/sunlight), so as to enhance the quality of the fingerprint image. Further, the existing manufacturing process of the display includes the process to manufacture the color filter. Therefore, manufacturing the color filter is easy, and the cost of the total manufacturing process is low.

In yet another embodiment of the disclosure, the first photosensors of the optical sensor receive the green light and the blue light passing through the filter layer and the first color filters from the finger to determine the first fingerprint image of the finger. The second photosensors of the optical sensor receive the red light passing through the filter layer and the second color filters from the finger to determine the second fingerprint image of the finger. The fingerprint image of the finger is determined according to the first fingerprint image and the second fingerprint image, so as to improve the accuracy of the fingerprint identification apparatus.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

1. A fingerprint identification apparatus for detecting a fingerprint image of a finger, comprising:
a display, configured to emit light and having a fingerprint imaging area;
an optical sensor; and
a control device, wherein the control device drives a region of the display at the periphery of the fingerprint imaging area to emit light to the finger when the finger touches the fingerprint imaging area, and the optical sensor is configured to receive light reflected from the finger touching the fingerprint imaging area to determine the fingerprint image of the finger.

2. The fingerprint identification apparatus as recited in claim 1, wherein the display comprises a plurality of pixels, and each of the pixels comprises a red subpixel, when the finger touches the fingerprint imaging area, the control device drives the red subpixels at the region of the display at the periphery of the fingerprint imaging area to emit red light to the finger.

3. The fingerprint identification apparatus as recited in claim 1, wherein the control device is a thin film transistor circuitry disposed in the display.

4. The fingerprint identification apparatus as recited in claim 1, wherein the optical sensor comprises a plurality of photosensors.

5. The fingerprint identification apparatus as recited in claim 1, wherein the optical sensor is disposed in the display.

6. The fingerprint identification apparatus as recited in claim 1, wherein the optical sensor is disposed under the display.

7. The fingerprint identification apparatus as recited in claim 6, further comprising a collimator disposed between the display and the optical sensor.

8. The fingerprint identification apparatus as recited in claim 6, further comprising a lens disposed between the display and the optical sensor.

9. A fingerprint identification apparatus for detecting a fingerprint image of a finger, comprising:
a display, having a fingerprint imaging area, and configured to have a plurality of pixels;
an optical sensor, comprising a plurality of first photosensors, and disposed in the display;
a filter layer, disposed in the display, disposed above the pixels and the optical sensor, and configured to block infrared light and allow visible light to pass through;
a plurality of first color filters, disposed between the filter layer and the first photosensors, and configured to block red light, each of the first color filters covering one of the first photosensors; and
a control device, wherein the control device drives the pixels at the fingerprint imaging area to emit visible light to the finger when the finger touches the fingerprint imaging area, and each of the first photosensors receives light passing through the filter layer and the corresponding first color filter from the finger to determine a first fingerprint image of the finger.

10. The fingerprint identification apparatus as recited in claim 9, wherein the control device is a thin film transistor circuitry disposed in the display.

11. The fingerprint identification apparatus as recited in claim 9, wherein each of the pixels comprises a red subpixel, a blue subpixel, and a green subpixel.

12. The fingerprint identification apparatus as recited in claim 11, wherein the light passing through the filter layer and the corresponding first color filter from the finger to each of the first photosensors is green light and blue light.

13. The fingerprint identification apparatus as recited in claim 9, wherein the filter layer is an infrared light cut filter layer, and each of the first color filters is a cyan color filter.

14. The fingerprint identification apparatus as recited in claim 9, wherein the fingerprint image of the finger is determined according to the first finger image.

15. The fingerprint identification apparatus as recited in claim 9, further comprising a plurality of second color filters, wherein the optical sensor further comprises a plurality of second photosensors, the filter layer is disposed above the second photosensors, the second color filters are disposed between the filter layer and the second photosensors and each of the second color filters covers the corresponding second photosensors, and each of the second photosensors receives light passing through the filter layer and the corresponding second color filter from the finger to determine a second fingerprint image of the finger.

16. The fingerprint identification apparatus as recited in claim 15, wherein the light passing through the filter layer and the corresponding second color filter from the finger to each of the second optical sensors is red light.

17. The fingerprint identification apparatus as recited in claim 15, wherein the filter layer is an infrared light cut filter layer, each of the first color filters is a cyan color filter, and each of the second color filters is a red color filter.

18. The fingerprint identification apparatus as recited in claim 15, wherein the fingerprint image of the finger is determined according to the first fingerprint image and the second fingerprint image.

19. The fingerprint identification apparatus as recited in claim 15, wherein the first photosensors and the second photosensors are arranged in chess board manner.
